(19) United States
(12) Patent Application Publication
(10) Pub. No.: US 2025/0311638 A1
(43) Pub. Date: Oct. 2, 2025

(54) SCALABLE SPINTRONIC DEVICES FORMED ON SILICON WAFERS

(71) Applicants: Regents of the University of Minnesota, Minneapolis, MN (US); Government of the United States of America, as represented by the Secretary of Commerce, Gaithersburg, MD (US); Theiss Research, Inc., La Jolla, CA (US)

(72) Inventors: Jian-Ping Wang, Shoreview, MN (US); Deyuan Lyu, Minneapolis, MN (US); Daniel B. Gopman, Gaithersburg, MD (US); Jenae E. Shoup, La Jolla, CA (US)

(21) Appl. No.: 18/435,084

(22) Filed: Feb. 7, 2024

Related U.S. Application Data
(60) Provisional application No. 63/483,667, filed on Feb. 7, 2023.

(51) Int. Cl. H10N 50/85; H10B 61/00; H10N 50/01; H10N 50/10

(52) U.S. Cl. CPC H10N 50/85; H10B 61/20; H10N 50/01; H10N 50/10

(57) ABSTRACT

A device which includes a silicon wafer substrate and a seed layer formed on a surface of the silicon wafer substrate. The device also includes a perpendicular magnetic anisotropy (PMA) layer exhibiting crystalline PMA formed on the seed layer, wherein the PMA structure comprises at least one of iron-palladium (FePd) alloy, iron-platinum alloy (FePt), or iron-platinum-palladium alloy (Fe(PtₓPd₍₁₋ₓ₎).

This application claims the benefit of U.S. Provisional Patent Application No. 63/483,667, filed 7 Feb. 2023, the entire contents of which is incorporated herein by reference.

### GOVERNMENT INTEREST

This invention was made with government support under 70NANB22H075 awarded by the National Institute of Standards and Technology, and FA8650-18-2-7868 awarded by the Department of the Air Force, and HR0011-17-S-0056-FP042 awarded by the Defense Advanced Research Projects Agency. The government has certain rights in the invention.

### BACKGROUND

With the advent of mobile and handheld electronic devices, the demand for much smaller, faster and ultra-low power systems keeps growing. The increasing density of complementary memories has caused significant increases in static and dynamic power consumption in electronic devices.

### SUMMARY

In some examples, the disclosure is directed to a device which includes a silicon wafer substrate, a seed layer formed on a surface of the silicon wafer substrate, a dual buffer layer (bilayer buffer or bridge layer), and a ferromagnetic layer exhibiting crystalline perpendicular magnetic anisotropy (“PMA structure”) formed on the bilayer buffer (“bridge layer”). The PMA structure includes at least one of iron-palladium (FePd) alloy, iron-platinum alloy (FePt), or iron-platinum-palladium alloy (Fe(PtₓPd₍₁₋ₓ₎), and may include a synthetic antiferromagnetic (“SAF”) structure, in which plural FePd, FePt, or Fe(PtₓPd₍₁₋ₓ₎) layers antiferromagnetically coupled through a spacing layer.

In some examples, the disclosure is directed to a technique which includes receiving a silicon wafer substrate. The technique also includes forming a seed layer on a surface of the silicon wafer substrate. Additionally, the technique includes forming a PMA structure on the seed layer. The PMA structure includes at least one of iron-palladium (FePd) alloy, iron-platinum alloy (FePt), or iron-platinum-palladium alloy (Fe(PtₓPd₍₁₋ₓ₎).

In some examples, the disclosure is directed to a spin-orbit torque (SOT) MRAM device or a logic device. The device includes a silicon wafer substrate, a seed layer formed on a surface of the silicon wafer substrate, a perpendicular magnetic anisotropy (PMA) structure exhibiting crystalline PMA formed on the seed layer, wherein the PMA structure comprises at least one of iron-palladium alloy (FePd), iron-platinum alloy (FePt), or iron-platinum-palladium alloy (Fe(PtₓPd₍₁₋ₓ₎), a magnetic tunnel junction (MTJ) structure including a MgO tunnel barrier, a hard perpendicular magnetic anisotropy (PMA) layer with a pinned magnetization orientation, and a soft PMA layer with a settable magnetization orientation. Additionally, in some examples, the device includes a bridge layer between the MTJ structure and the FePd, FePt, or Fe(PtₓPd₍₁₋ₓ₎) layer.

In some examples, the disclosure is directed to a device which includes a silicon wafer substrate with pre-patterned transistors structures and metal layers including a top metal layer, a seed layer formed on a surface of the top metal layer, and a perpendicular magnetic anisotropy (PMA) structure exhibiting crystalline PMA formed on the seed layer. The PMA structure comprises at least one of iron-palladium (FePd) alloy, iron-platinum alloy (FePt), or iron-platinum-palladium alloy (Fe(PtₓPd₍₁₋ₓ₎).

The details of one or more examples are set forth in the accompanying drawings and the description below. Other features, objects, and advantages will be apparent from the description and drawings, and from the claims.

### BRIEF DESCRIPTION OF DRAWINGS

FIG. 1A-1B are charts comparing thermal stability scales as a function of PMA structure thickness and device diameter. FIGS. 1A and 1B respectively plot the thermal stability of conventional PMA material (Co—Fe—B alloy) and Fe—Pd alloy.

FIG. 2A illustrates a schematic stack structure of example devices with and without a seed layer.

FIG. 2B is a chart illustrating hysteresis loops of (001)-textured L1₀-FePd (solid symbols) and the control sample (empty symbols).

FIG. 2C is a chart illustrating R_{AH}-Hₑₓₜ loops collected from a 10×78 μm² Hall bar device at different temperatures. Inset: An optical microscopy image of the device. The Hall bar channel is labelled by black dashed line.

FIG. 2D is an MFM image of a 5×5 μm² portion of the (001)-textured L1₀-FePd, where the markers indicate the direction of local magnetization.

FIG. 3A is a schematic illustration of the TR-MOKE measurements performed on an L1₀-FePd(001) example PMA structure according to the present disclosure.

FIG. 3B is a chart illustrating TR-MOKE signals, which reflect the damped precession of M induced by laser excitation, as functions of time delay.

FIG. 3C is a chart illustrating extracted f (top panel) and τ⁻¹ (bottom panel) vs. μ₀Hₑₓₜ.

FIG. 4A illustrates example reciprocal space XRD patterns of a portion of an example device according to the present disclosure.

FIG. 4B is a 3D representation of reciprocal space maps shown in FIG. 4A.

FIG. 4C is a chart illustrating θ-2θ spectrum of the XRD signal.

FIG. 5A is a cross-sectional HAADF image of a portion of an example device according to the present disclosure.

FIG. 5B is a cross-sectional image of a portion of the example sample of FIG. 5A.

FIG. 5C is a cross-sectional STEM image illustrating interfaces between the layers of an example device at atomic resolution.

FIG. 5D is a schematic diagram illustrating crystalline structures and estimated lattice parameters of L1₀-FePd, Pt, Ct, and MgO.

FIGS. 6A-6D illustrate hysteresis loops of FePd-based p-SAFs.

FIG. 7A is cross-sectional HRTEM image of an FePd-based p-SAF.

FIG. 7B is a STEM-HAADF image of an L1₀-FePd/Ir/L1₀-FePd trilayer PMA structure.

FIG. 7C illustrates NBD patterns collected within a single grain and their overlap.

FIG. 8 is a schematic cross-sectional diagram illustrating an example device according to the present disclosure.

FIG. 9 is a flowchart illustrating an example technique for forming a device according to the present disclosure.

### DETAILED DESCRIPTION

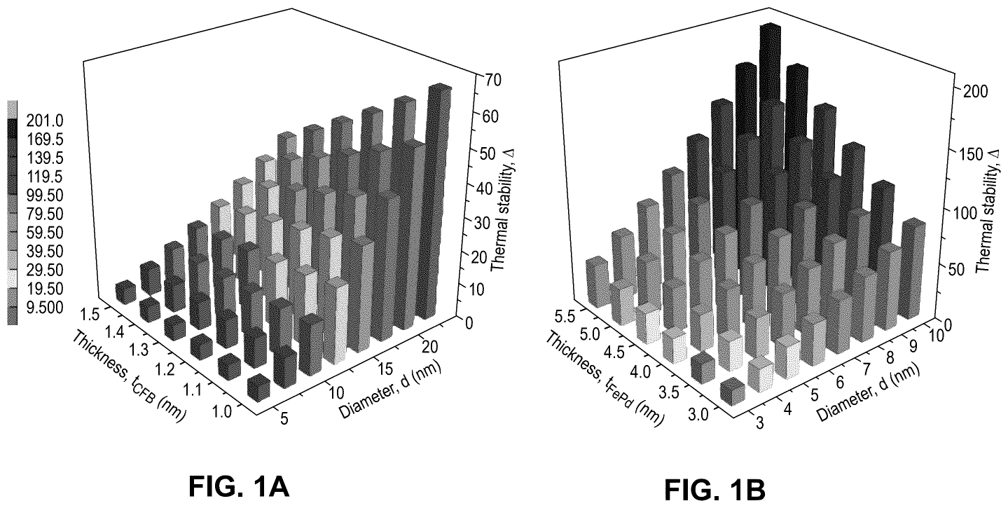

Materials and layered structures that possess perpendicular magnetic anisotropy (PMA) have drawn significant interest in both applied and fundamental research within magnetism and spintronics for the past two decades. Due to their promised advantages (e.g., scalability, speed, energy dissipation, etc.) over in-plane counterparts, PMA materials including rare earth-transition metal (RE-TM) compounds, Co (or CoFe)-based multilayers, and L1₀-phase alloys were widely investigated as potential material choices for future memory and logic devices until the 2010s. Unfortunately, they either lack the tolerance to required thermal treatments (e.g., the 400° C. annealing in back-end-of-line semiconductor processes), suffer from large Gilbert damping (α), or otherwise require epitaxy with substrate materials incompatible with monolithic semiconductor integration. In contrast, as-deposited CoFeB is amorphous and can crystalize during post-annealing by solid-state epitaxy (SSE), forming sharp CoFe(B)—MgO interfaces and enabling giant tunnel magnetoresistance (TMR). Thus, the CoFeB/MgO system quickly became the mainstream after the discovery of its interfacial PMA in 2010, and CoFeB/MgO systems dominated the development of perpendicular-magnetic tunnel junctions (p-MTJs) in the last decade. However, CoFeB/MgO systems suffer from drawbacks including weak interfacial PMA (K_{i,CFB}˜1.5 mJ m⁻²), which may limit the thickness (t) of CoFeB to ˜1.3 nm. As p-MTJ size (diameter, d) entered a single-digit nm era, the combination of small t_{CFB} and d, as shown in FIG. 1A, leads to insufficient thermal stability (Δ) of below 20 and directly restricts the nonvolatility of p-MTJ devices. FIG. 1A illustrates the thermal stability of CoFeB. In the t regime where interfacial PMA makes CoFeB perpendicularly magnetized (t_{CFB}˜1.3 nm), Δ is always less than 20 at d≤10 nm. To make CoFeB-based p-MTJs more scalable, additional efforts like utilizing shape anisotropy (t≥10 nm) and creating multiple (Co)FeB—MgO interfaces have to be taken, which significantly increases switching current density (J, proportional to t) and stack complexity.

This disclosure describes example techniques to accompany the continued shrinking down of nanoscale spintronic devices that may overcome issues described above. However, the techniques described in this disclosure should not be considered limited to overcoming the issues described above.

L1₀-FePd manifests strong bulk PMA of K_{b,FePd}˜1.7 MJ m⁻³ and thus, exhibits excellent scalability. As shown in FIG. 1B, Δ=60 that corresponds to ˜10 year data retention can be reached at d=5 nm with a moderate t_{FePd}˜5 nm. As a free layer material, L1₀-FePd may be applied in full p-MTJs and read sensor-type MTJs (with in-plane reference layer), in which a projected TMR up to 85% may be realized. FIG. 1B illustrates the thermal stability of L1₀-FePd. Due to its strong bulk, PMA, L1₀-FePd can sustain 4 of exceeding 60 at a moderate t_{FePd}˜5 nm while downscaling to d=5 nm. The parameters of CoFeB and L1₀-FePd are assumed to be K_{i,CFB}=1.5 mJ m⁻², K_{b,FePd}=1.7 MJ m⁻³, and saturation magnetization M_{S,CFB}=1.2 MA m⁻¹ and M_{S,FePd}=1.1 MA m⁻¹, respectively. Devices which include an L1₀-FePd free layer may provide unforeseen energy efficiency in bipolar electric-field switched FePd p-MTJs through voltage-controlled exchange coupling. A free layer may be a layer within a device that has a configurable magnetization state. Such devices may achieve an ultralow J˜1.1×10⁵ A cm⁻². In one or more examples, the chemisorption-type van der Waals force and robust interfacial PMA of FePd-Graphene interface may provide benefits from integrating FePd-based spintronic devices with 2D materials. Additionally, the low α of FePd may outperform those of RE-TM compounds, Co (or CoFe)-based multilayers, and many other L1₀-alloys (e.g., L1₀-FePt). As such, FePd alloys may be highly desirable for device applications because J is proportional to α. Example devices and magnetic structures which include FePd composite free layers are the subject of U.S. Pat. No. 10,546,997 B2 to Wang et al., the entire contents of which is incorporated herein in entirety.

Despite the advantages of L1₀-FePd, its PMA and damping depend on the crystallinity of L1₀ phase and (001) texture. In order to seed a strong (001)-textured L1₀ order, only a few special substrates, such as MgO(001) and SrTiO₃ (001), may be suitable for L1₀-FePd growth. These substrates are costly, hard to obtain in large sizes, and most severely, incompatible to the monolithic integration with semiconductor microelectronics. As a result, applying L1₀-FePd to extend the scalability of spintronic devices may present challenges.

In devices and techniques according to the present disclosure, it is demonstrated that synthesizing L1₀-FePd with (001) texture on industry-ready thermally-oxidized Si wafers by magnetron sputtering may be accomplished. Example devices are disclosed, which have been characterized by vibrating-sample magnetometry (VSM) and ultrafast time-resolved magneto-optical Kerr effect (TR-MOKE) metrology. The example devices exhibit strong PMA with full out-of-plane remanence (Mᵣ), high in-plane saturation field (H_{S}), as well as low α. X-ray diffraction (XRD) measurements confirm the L1₀ phase and strong (001) texture. In some examples, the L1₀-FePd(001) texture is induced by a (001)-textured MgO seed layer, which was prepared by industry-compatible radio-frequency (RF) magnetron sputtering at room temperature on the amorphous SiO₂ surface. Atomic-resolution scanning transmission electron microscopy (STEM) reveals the epitaxial growth of buffer layer (001)/L1₀-FePd(001) on MgO(001). Given that MgO is part of the general techniques using p-MTJ material systems, this disclosure provides an accessible pathway to enable deeply-scalable spintronic applications. Moreover, in some examples, devices are disclosed which include perpendicular-synthetic antiferromagnets (p-SAFs) that include two L1₀-FePd layers antiferromagnetically coupled through an Ir spacer, although other types of spacers may be possible. In some examples, the Ir-spaced FePd p-SAFs prepared on Si/SiO₂ wafers exhibit very large interlayer exchange coupling (IEC, −Jₑₓ), up to ˜34% higher than the Ru-spaced p-SAF on MgO(001) substrates. As p-SAFs have been experimentally demonstrated to perform better than uniform ferromagnets with faster speed, higher 4, as well as lower J, this result further exhibits one or more examples of the technological potential of devices according to the present disclosure.

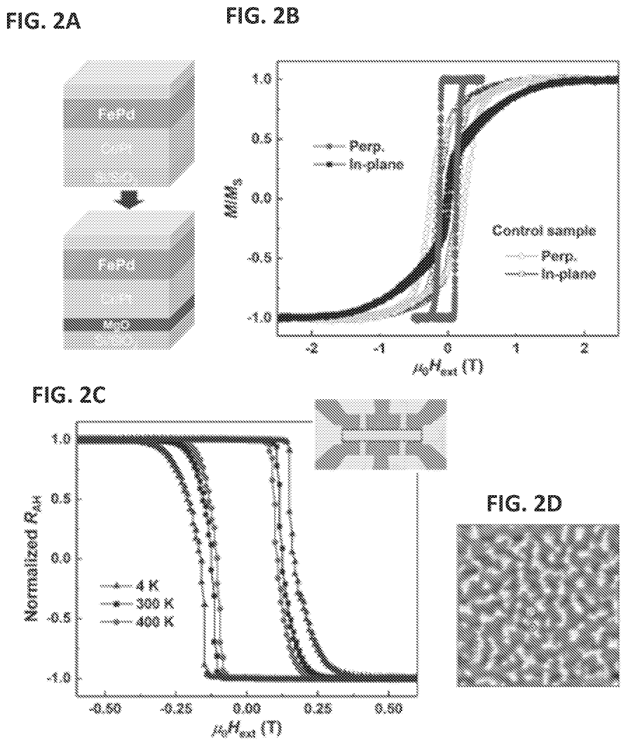

An example device according to the present disclosure is illustrated in FIG. 2A. Stack structure of the samples with (bottom) and without (top) the MgO seed layer. The one without the MgO seed layer served as a control sample. The stacks containing a Cr/Pt bilayer buffer and the FePd layer were direct-current magnetron sputtered onto Si(001)/SiO₂ (300 nm, thermally oxidized) wafers with/without an RF sputtered MgO seed layer, followed by a capping layer. In some examples, the Cr buffer is an example of a bridge layer, and the Pt buffer is another example of a bridge layer, and in some cases, may be formed together and referred to as a bridge layer. Other examples of bridge layers are possible. Except for the 5 nm MgO that was deposited in an auxiliary chamber (Oerlikon Leybold Vacuum UNIVEX MULTICHAMBER, base vacuum better than 3×10⁻⁹ Torr) at room temperature, all the layers were prepared in a custom ultrahigh vacuum chamber with base pressure better than 5×10⁻¹⁰ Torr. Before the deposition of Cr, the MgO-coated wafers were baked at 600° C. for 1 h in vacuum and held for an additional 0.5 h in an 0.8 mTorr N₂ environment to heal any oxygen vacancies known to form on the surface of MgO during vacuum annealing. The Cr(30 nm)/Pt(4 nm) buffer and 8 nm FePd layer were grown at 350° C. with a 10 min in-situ anneal at 600° C. performed after the Cr layer deposition for stress relief. Finally, a Ru (2 nm)/Ta (3 nm) capping layer was grown after cooling the substrate down to room temperature. The sputtering was at Ar pressure of 2 mTorr, 3 mTorr, and 6 mTorr for MgO, Cr/Pt, and FePd, respectively.

The magnetization (M)-external field (Hₑₓₜ) hysteresis loops of FePd layers were measured by VSM and plotted in FIG. 2B. Despite the amorphous SiO₂ surface, FePd shows strong PMA with Mᵣ=M_{S} and μ₀H_{S}˜2 T with the insertion of MgO seed layer, indicating its (001)-textured L1₀ phase. By integrating over the in-plane curve, the uniaxial anisotropy energy density (Kᵤ) is estimated to be 1.13 MJ m⁻³, about 60% higher than the case of (Mn—Cr)AlGe and comparable with results of FePd formed on MgO(001) or SrTiO₃ (001) substrates. Compared with efforts such as crystalizing FePdB by SSE, performing long-time annealing in H₂, precisely controlling the heating rate, trying various buffers, and alloying FePd with Cu, the example device was formed using a deliberately uncomplicated technique and uniquely achieves distinct PMA of FePd with amorphous substrates. The control sample (i.e., without the MgO seed layer) shows a significant in-plane component of the easy axis. As the PMA follows the orientation of the (001)-textured L1₀ phase, the VSM measurements imply that the MgO seed layer is key to engineer the correct FePd microstructure. To further explore its application potential, the PMA FePd was patterned into Hall bar devices by using photolithography and Ar⁺ ion milling. Top-contact pads made of Ti (10 nm)/Au (100 nm) were fabricated by E-beam evaporation and a lift-off process. The Hₑₓₜ-dependence of anomalous Hall resistance (R_{AH}) and device geometry are presented in FIG. 2C and its inset, respectively. The R_{AH}-Hₑₓₜ loops collected from a cryogenic temperature of 4 K to a high temperature of 400 K show that FePd maintains its PMA in a wide temperature range. FePd-based spintronic devices, as a result, manifest a broad application prospect from superconducting circuits (˜4 K) to automotive grade-1 products (−40° C. to 125° C.). FIG. 2D presents a magnetic force microscopy (MFM) image of the MgO-seeded FePd film in the demagnetized state, showing the labyrinth domain structure typical of perpendicularly magnetized films. The observed sub-micron magnetic domain size is comparable to those observed in FePd films grown on MgO(001) substrates.

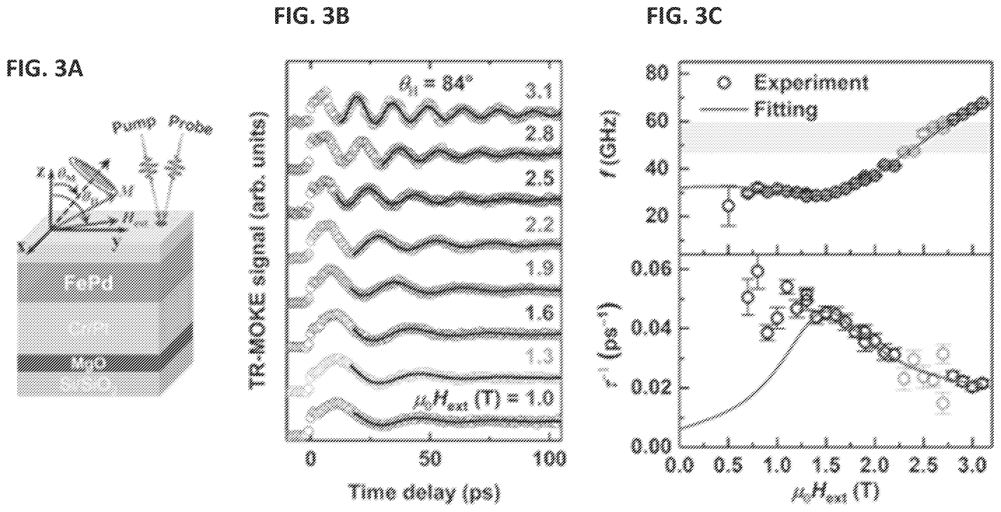

The magnetic characteristics of example PMA structures was further investigated. TR-MOKE measurements were conducted on the L1₀-FePd(001) thin film, and the results are illustrated schematically as shown in FIG. 3A, where θ_{H} and θ_{M} respectively denote the direction of Hₑₓₜ and resulted equilibrium angle of M.

A representative set of TR-MOKE signals and associated fitting results are plotted in FIG. 3B as functions of the time delay between pump excitation and probe sensing. The experimental data and fitting curves are marked by circles and lines, respectively. The experiments are conducted under μ₀Hₑₓₜ ranging from 1.0 to 3.1 T along θ_{H}=84° deviating from the surface normal. Here, θ_{H}=84° was chosen to balance the needs for precessional signal amplitudes and the measurement sensitivity to a. FIG. 3C summarizes the corresponding precession frequency (f, top panel) and relaxation time (t, bottom panel) that are extracted from the damped magnetization oscillation observed in experiments. The best fits of field-dependent f and τ⁻¹ yield μ₀Hₖ=1.33±0.06 T and α=0.012±0.007. Due to the spin-strain coupling, translucent data points (highlighted region) are excluded from the fitting. The translucent data points are excluded from fitting to avoid the influence of the laser-induced acoustic waves (˜56 GHz±3 GHz measured with the time-domain thermoreflectance technique) via spin-strain coupling. At low fields (μ₀Hₑₓₜ<1.4 T), the measured τ deviate markedly from the model fit, which can be explained by the low-field loss.

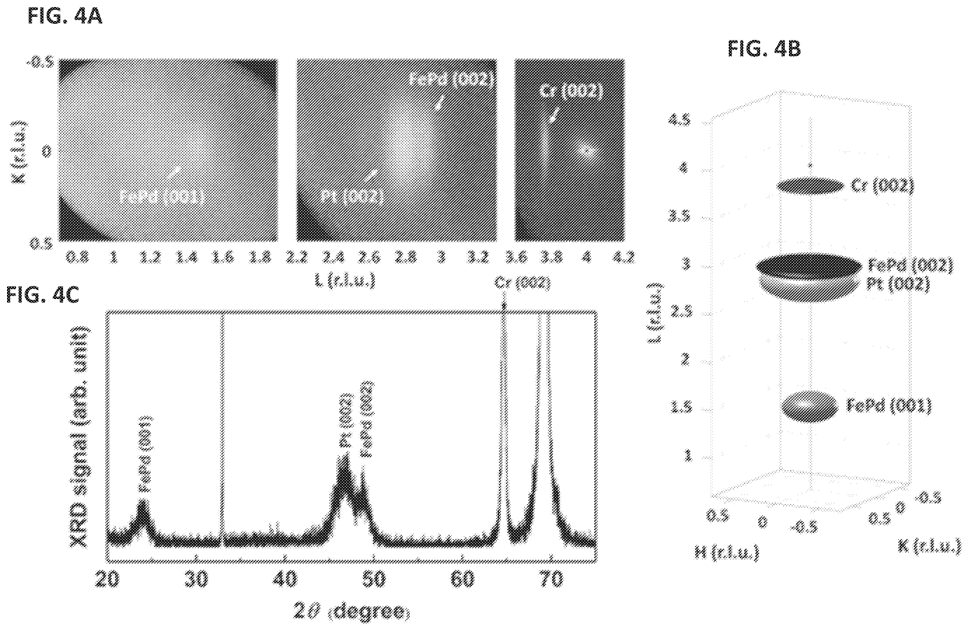

The crystal structures and registry between layers of an example device were explored by X-ray diffraction (XRD) studies. By using a Bruker D8 Discover microdiffractometer equipped with a Vantec 500 2D detector and a Hubber ¼ Eulerian cradle, reciprocal space maps of the sample were collected. The scattering peaks of individual layers are assigned in different panels of FIG. 4A. In FIG. 4A, the illustrations include large area reciprocal space maps (HL projection). The scattered intensity is represented with a temperature-colored scale. From left to right, the FePd(001) peak can be identified, confirming the strong (001) texture and L1₀ ordering of FePd sputtered on Si/SiO₂ wafers, as well as the Pt(002) and FePd(002) peaks, which are close to each other but still distinguishable, and the Cr(002) peak. Both the bilayer buffer and FePd obeyed (001)-textured growth on the MgO layer, which may be a precondition of the high PMA and low α of L1₀-FePd(001).

It was also observed that the structural coherence of the layers is better in the direction of the growth than in the in-plane directions, which highlights the good crystalline quality of the layers despite the granular-oriented morphology imposed by the MgO layer. The high crystallinity and strong texture of the sample can be better visualized in FIG. 4B, where the peak intensity in HL and KL projections (H, K and L reflect the coordinate basis associated with the crystal) are extracted, temperature-colored with a scale approximately matching the one of FIG. 4A, and presented in a 3D form. In FIG. 4B, the 3D representation is of the 00L specular rod. In this representation, the scattering ellipsoids are obtained from the fitting of individual peaks in both the HL and KL projections.

The conventional θ-2θ spectrum is plotted in FIG. 4C. Based on the peak positions and intensity, the out-of-plane lattice parameters of Cr, Pt, and FePd are estimated to be (2.88±0.01) Å, (3.90±0.03) Å, and (3.73±0.02) Å, respectively, in which uncertainties are associated with pseudo-Voigt fits to the data. The L1₀ ordering parameter(S) of FePd is calculated to be 0.73±0.01, also comparable to the counterparts using MgO(001) or SrTiO₃(001) substrates. The MgO peaks are not observed due to its small thickness t_{MgO}=5 nm and low electron density, however the crystallinity of the MgO layer is later confirmed with STEM measurements. The unlabeled peaks with very high intensity and narrow spread are from the substrate lattice.

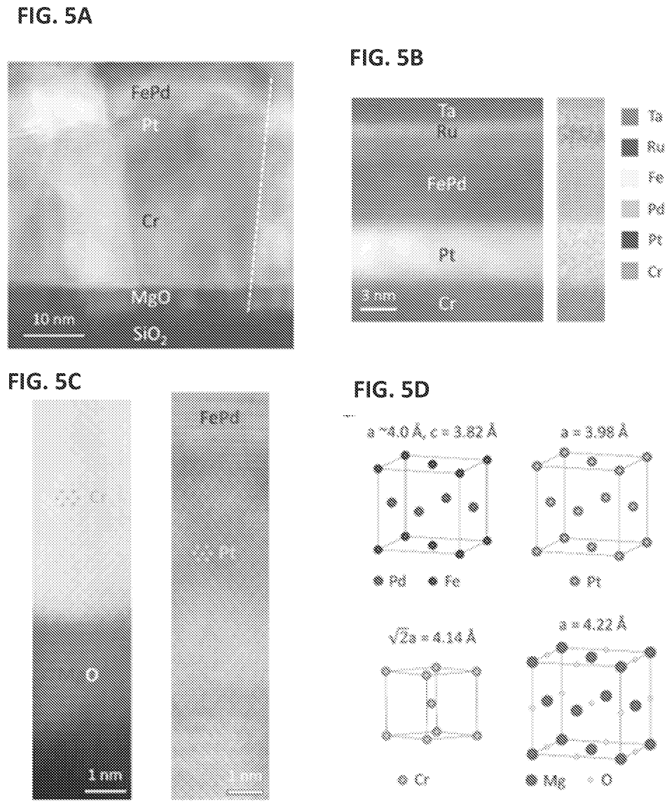

The microstructure of the MgO layer and the epitaxial relationship of the stack were studied by STEM. FIG. 5A shows a cross-sectional image of the stack under the high-angle annular dark field (HAADF) mode. The dashed line marks a grain boundary. It is clear that both the bilayer buffer and L1₀-FePd followed a grain-on-grain heteroepitaxial growth on textured MgO. The grain boundaries, one of which is marked by the dashed line, are shared by the MgO seed layer, bilayer buffer, as well as FePd. This epitaxial growth is established from MgO since it tends to form (001) texture on amorphous surfaces, of which CoFeB is a known example. A zoomed-in image around the FePd layer and the energy dispersive X-ray (EDX) profile is shown in FIG. 5B. The portion illustrates the L1₀-FePd and EDX elemental distribution. As illustrated, the interfaces are flat and sharp, showing no significant interdiffusion during the sputtering and annealing processes. By taking atomic-resolution images (FIG. 5C) and nanobeam diffraction (NBD) patterns (shown later), the lattice parameters of each layer were estimated, as illustrated in FIG. 5D. The lattice parameters are consistent with the values obtained from XRD measurements. The epitaxial relationship was inferred to be MgO (001)/Cr [110](001)/Pt [100](001)/L1₀-FePd [100](001), in which the Cr/Pt buffer can effectively release the lattice misfit between MgO and L1₀-FePd.

In addition, FePd-based p-SAFs on Si/SiO₂ wafers were prepared by inserting a sub-nm Ir spacer (tₗᵣ is wedged from 4.5 to 6.0 Å) between two L1₀-FePd layers.

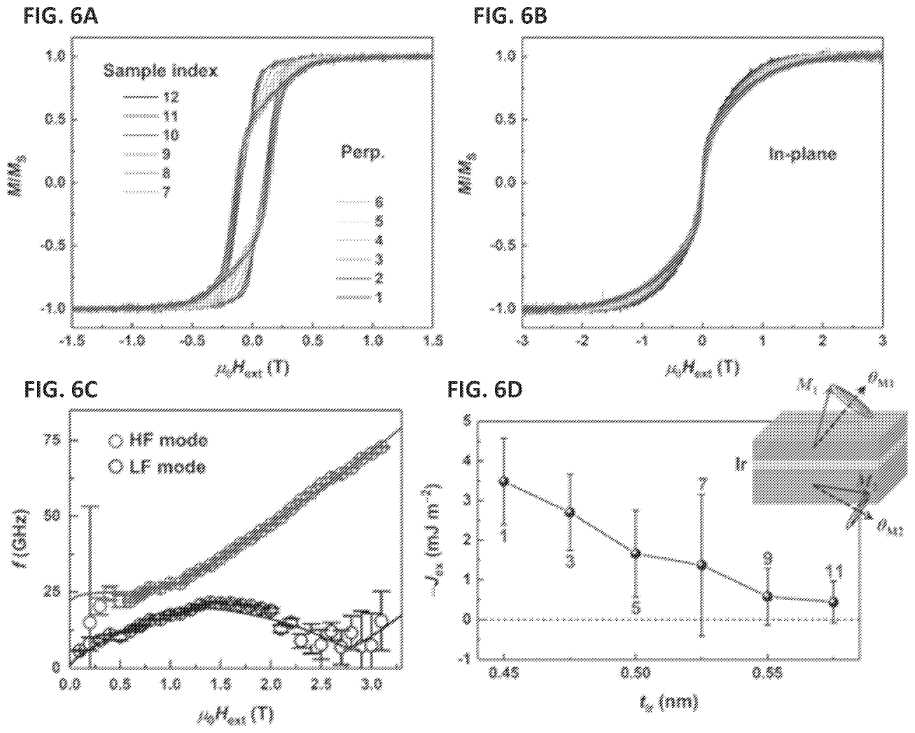

The samples were cleaved along the wedge direction and indexed from 1 to 12. Their M-Hₑₓₜ hysteresis loops, as shown in FIG. 6A and FIG. 6B, indicate strong PMA with all tₗᵣ and markedly larger in-plane saturation field (by nearly 1 T magnitude) compared to the out-of-plane saturation field. That is, both the top and bottom FePd layers are (001)-textured. By increasing fir, the M-Hₑₓₜ loop gradually changes from a compensated antiferromagnetic configuration to a ferromagnetic-like configuration in which two FePd layers reverse almost coherently. That means, within the tₗᵣ range of this study, a monotonic decrease of IEC strength as tₗᵣ increases. FIG. 6A illustrates the perpendicular direction, while FIG. 6B illustrate the in-plane Hₑₓₜ. FIG. 6C illustrates field-dependent f of HF and LF in Sample 1 (θ_{H}=) 85°. Circles and lines denote measurement data and theoretical fits, respectively. FIG. 6D is a chart illustrating −Jₑₓ of FePd-based p-SAFs vs. sample index (by number) and nominal tr. Inset: Schematic of high-fidelity TR-MOKE metrology developed to study p-SAFs. M₁, M₂, θ_{M1}, and θ_{M2} denote the magnetization of the top and bottom L1₀-FePd layers and their equilibrium angles under Hₑₓₜ, respectively.

Based on SAF magnetization switching behaviors, the top FePd layer is found to switch first as it was prepared to be thinner (3 nm) than the bottom FePd layer (6 nm). In the M-Hₑₓₜ loops of low index samples, the gradual transition of the magnetizations from antiparallel to parallel is consistent with the magnetic free energy of a p-SAF with Ku near parity with −Jₑₓ/t_{FePd,top}. Since overcoming PMA to rotate L1₀-FePd layers into the plane and IEC to force them aligned cost certain amounts of Zeeman energy, the anisotropy and exchange fields should be approximately additive. Assuming the intrinsic magnetic properties of L1₀-FePd layers remain constant among such a narrow fir range of only ˜1.5 Å, the areas contoured by two in-plane hysteresis curves should reflect their difference in the IEC energy. Therefore, it is also observed that −Jₑₓ decreases as tₗᵣ increases. To quantitatively measure −Jₑₓ, the TR-MOKE technique was employed to study the p-SAFs as a function of τₗᵣ. Capable of measuring dynamics up to the THz range, TR-MOKE is a powerful tool to characterize p-SAFs with high PMA and IEC. By fitting the field-dependent f in the high-(HF) and low-frequency (LF) modes, Jₑₓ can be calculated by Jₑₓ=J₁+2J₂, with J₁ and J₂ the extracted bilinear and biquadratic exchange coupling constants, respectively.

As a representative example, FIG. 6C shows the field-dependence off in both precessional modes of Sample 1. The fitting curve gives −Jₑₓ=3.48±1.09 mJ m⁻², which is ˜34% larger compared to the former result. In FIG. 6D, −Jₑₓ is plotted as a function of sample index and nominal tₗᵣ. In agreement with VSM results, −Jₑₓ decreases as tₗᵣ increases, indicating the coverage of tₗᵣ by the first (and strongest) antiferromagnetic range of Ir's Ruderman-Kittel-Kasuya-Yosida (RKKY) oscillation. A sketch of the p-SAF trilayer and TR-MOKE metrology is shown as the inset of FIG. 6D. Given the multiple advantages of p-SAFs over single-magnet counterparts, the FePd-based p-SAFs prepared on Si/SiO₂ wafers can further advance the application of scalable spintronic devices.

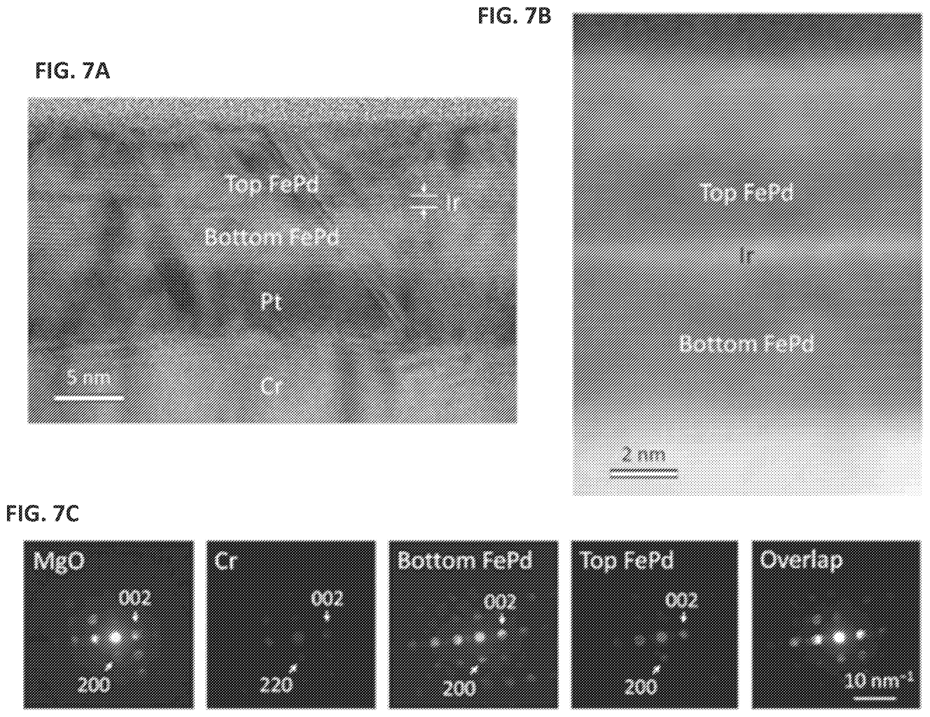

One example for the enhancement of −Jₑₓ is attributed to the strong RKKY interaction of Ir as well as proper seed and buffer layers of L1₀-FePd on amorphous SiO₂ surface. To elucidate the high performance of L1₀-FePd/Ir/L1₀-FePd p-SAFs, high-resolution transmission electron microscopy (HRTEM) and STEM were performed to investigate their microstructure. As shown in FIG. 7A, the high crystallinity of both the top and bottom FePd layers is confirmed. Though the Ir spacer is ultrathin, it is still observable. By using the STEM-HAADF mode, the Ir spacer can be imaged with better contrast as shown in FIG. 7B, where the two FePd slabs are separated by a continuous Ir band. To illustrate the epitaxial relationship between each layer, especially the two FePd layers, NBD measurements to a single grain were conducted. The results, as presented in FIG. 7C, show a grain-on-grain heteroepitaxy through the Ir layer. Specifically, the SAF trilayer is textured as L1₀-FePd [100](001)/Ir/L1₀-FePd [100](001). Such an epitaxial growth, together with the sharp and flat interfaces between each layer, enables the considerable improvement in −Jₑₓ.

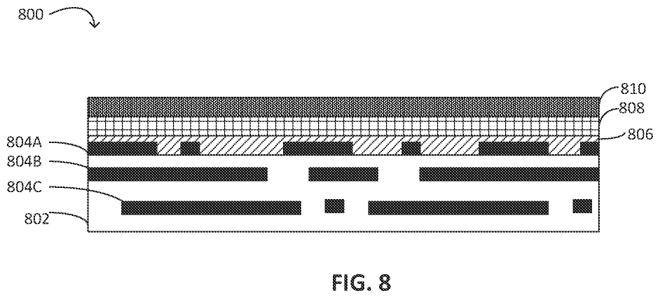

FIG. 8 is a cross-sectional diagram illustrating example device 800. Example device may be an example of the bottom stack of FIG. 2A. Device 800 includes silicon wafer substrate 802. Silicon wafer substrate 802 includes a plurality of metal layers 804A, 804B, and 804C (“metal layers 804”). Metal layers 804 may combine with silicon wafer substrate 802 to define a plurality of pre-patterned transistor structures (“CMOS structures”). Top metal layer 804A may be covered by seed layer 806, which may be configured to allow epitaxial growth of further layers as described above. For example, device 800 may include one or more bridge layers 808 (buffer layers). Device 800 may include PMA structure 810. PMA structure 810 may include at least one of iron-palladium (FePd) alloy, iron-platinum alloy (FePt), or iron-platinum-palladium alloy (Fe(PtₓPd₍₁₋ₓ₎).

In one or more examples, device 800 is a CMOS device, such as may be part of an integrated circuit. For instance, PMA structure 810 and bridge layers 808 may together form part of a MTJ structure used for bit storage. As another example, PMA structure 810 and bridge layers 808 may together form part of the integrated circuit to control impedance, be coupled to transistors, from part of a memory device, form part of a logic device, etc. In some examples, device 800 may be a (SOT) MRAM device or a logic device. In some examples, device 800 may include silicon wafer substrate 802, seed layer 806 formed on a surface of silicon wafer substrate 802, perpendicular magnetic anisotropy (PMA) structure 810 exhibiting crystalline PMA formed on the seed layer, wherein PMA structure 810 includes at least one of iron-palladium alloy (FePd), iron-platinum alloy (FePt), or iron-platinum-palladium alloy (Fe(PtₓPd₍₁₋ₓ₎). In some examples, device 800 may further include a magnetic tunnel junction bridge layer including a MgO tunnel barrier (not illustrated in FIG. 8) formed on PMA structure 810 and a hard perpendicular magnetic anisotropy (PMA) structure (not illustrated in FIG. 8). The hard PMA structure may exhibit PMA, ad may be formed on the magnetic tunnel junction bridge layer so that it acts as a tunnel barrier with a pinned magnetization orientation. Device 800 may further include a conducting layer (not illustrated in FIG. 8) formed on the hard PMA structure. A current delivered through the conducting layer, hard PMA structure, and the PMA structure may set a magnetization state of the PMA structure. In such examples, electrical stimulation of the SOT MRAM device may include measuring the tunneling magnetoresistance of the MRAM device and/or may include writing the orientation of the PMA structure.

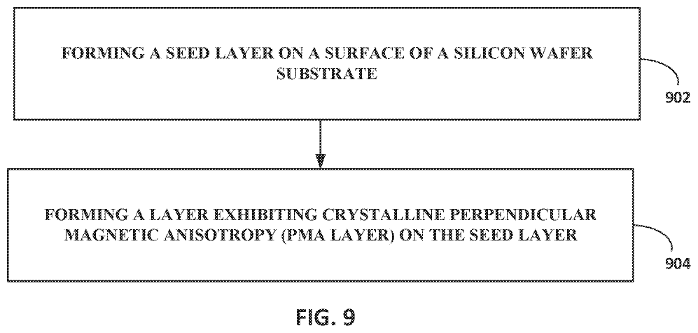

FIG. 9 is a flowchart illustrating an example technique for forming devices according to the present disclosure. The technique includes forming a seed layer on a surface of the silicon wafer substrate (902). In some examples, the seed layer may include at least one of magnesium oxide (MgO) or strontium titanate (SrTiO₃) having an (001) texture. The technique also includes forming a structure which exhibits crystalline perpendicular magnetic anisotropy (“PMA structure”) on the seed layer (904). In some examples, the PMA structure includes iron-palladium (FePd) alloy.

As used herein, “formed on” and “on” means a layer or coating that is formed on top of another layer or coating, and encompasses both a first layer or coating formed immediately adjacent a second layer or coating and a first layer or coating formed on top of a second layer or coating with one or more intermediate layers or coatings present between the first and second layers or coatings. In one or more examples, “formed directly on” and “directly on” denote a layer or coating that is formed immediately adjacent another layer or coating, i.e., there are no intermediate layers or coatings.

In summary, high-quality L1₀-FePd(001) thin films were deposited on industry-compatible Si/SiO₂ wafers. Without expensive MgO(001) or SrTiO₃(001) substrates, the FePd thin films still possess strong PMA and low damping constant (α) with suitable seed and buffer layers (which may also be called “bridge layers”). Furthermore, by adding an Ir spacer, p-SAFs with markedly improved IEC were also achieved. The high performance of both the L1₀-FePd single layer and its SAF indicates high crystallinity, strong (001) texture, as well as an epitaxial growth on amorphous SiO₂ surface. Comprehensive characterizations were performed to reveal the lattice details of the MgO seed layer, Cr/Pt bilayer buffer, L1₀-FePd, and its SAF and the epitaxial relationship throughout the stack. As MgO, the crucial seed layer material in this study, has been widely used by the spintronics community and is deposited by conventional RF sputtering, our results removed a key obstacle of applying L1₀-FePd for deeply-scalable spintronic devices.

Examples of the disclosure are illustrated by the following clauses and claims:

Clause 1. A device, comprising: a silicon wafer substrate; a seed layer formed on a surface of the silicon wafer substrate; and a perpendicular magnetic anisotropy (PMA) structure exhibiting crystalline PMA formed on the seed layer, wherein the PMA structure comprises iron-palladium (FePd) alloy.

Clause 2. The device of clause 1, wherein the device comprises at least a portion of a memory device or a logic device.

Clause 3. The device of any of clause 1 or clause 2, wherein the device comprises a magnetic tunnel junction (MTJ), and wherein the PMA structure is a free layer.

Clause 4. The device of any of clauses 1-3, wherein the silicon wafer comprises both elemental silicon (Si) and silicon dioxide (SiO₂).

Clause 5. The device of any of clauses 1-4, wherein the surface of the silicon wafer substrate silicon wafer is an amorphous SiO₂ surface.

Clause 6. The device of clause 5, wherein the surface of the silicon wafer substrate defines one or more metallized contacts, and the one or more metallized contacts comprise copper, aluminum, tungsten, or other metals.

Clause 7. The device of any of clauses 1-6, wherein the seed layer comprises at least one of magnesium oxide (MgO) or strontium titanate (SrTiO₃) having an (001) texture.

Clause 8. The device of any of clauses 1-7, wherein the seed layer is polycrystalline.

Clause 9. The device of any of clauses 1-8, wherein the seed layer is a thin film having a thickness measured normal to the surface of the silicon wafer substrate of from about 0.5 nanometers to about 20 nanometers, or from about 1 nanometer to about 8 nanometers, or from about 2 nanometers to about 7 nanometers.

Clause 10. The device of any of clauses 1-9, wherein the FePd alloy defines an L1₀-phase structure.

Clause 11. The device of any of clauses 1-10, further comprising at least one bridge layer between the seed layer and the PMA structure.

Clause 12. The device of clause 11, wherein the at least one bridge layer comprises two bridge layers including a first bridge layer and a second bridge layer.

Clause 13. The device of clause 12, wherein the first bridge layer comprises chromium and the second bridge layer comprises platinum.

Clause 14. The device of clause 13, wherein the first bridge layer and the second bridge layer each define a respective thickness measured normal to the surface of the silicon wafer substrate, wherein the thickness of the first bridge layer is from about 8 nanometers to about 30 nanometers, and wherein the thickness of the second bridge layer is from about 1 nanometer to about 10 nanometers.

Clause 15. The device of any of clause 1-14, wherein the PMA structure defines a thickness measured normal to the surface of the silicon wafer substrate, wherein the thickness is from about 2 nanometers to about 15 nanometers.

Clause 16. The device of any of clause 1-15, wherein the PMA structure is formed with a plurality of sub-layers that form a synthetic antiferromagnetic (SAF) structure.

Clause 17. The device of clause 16, wherein the sub-layers include three sub-layers, wherein two of the three sub-layers comprise FePd.

Clause 18. The device of clause 17, wherein one of the three sub-layers comprises one or more of iridium (Ir), ruthenium (Ru), rhodium (Rh), chromium (Cr), rhenium (Re), osmium (Os), molybdenum (Mo), or combinations thereof.

Clause 19. The device of any of clauses 17 or 18, wherein a sub-layer comprising Ir is formed between the sub-layers comprising FePd.

Clause 20. The device of any of clause 1-19, further comprising a capping layer formed on the PMA structure.

Clause 21. The device of clause 20, wherein the capping layer comprises at least one of ruthenium (Ru) or tantalum (Ta).

Clause 22. The device of any of clause 1-21, further comprising a magnetic tunnel junction bridge layer formed on the PMA structure.

Clause 23. The device of any of clauses 1-22, wherein the bridge layer comprises at least one of cobalt manganese silicide (Co₂MnSi), cobalt iron silicide (Co₂FeSi), cobalt manganese aluminide (Co₂MnAl), cobalt iron aluminide (Co₂FeAl), alloys of cobalt iron boride (Co—Fe—B), molybdenum (Mo), ruthenium (Ru), tantalum (Ta), magnesium oxide (MgO) or magnesium aluminum oxide (MgAl₂O₄).

Clause 24. A method, comprising: forming a seed layer on a surface of a silicon wafer substrate; and forming a perpendicular magnetic anisotropy (PMA) structure exhibiting crystalline PMA on the seed layer, wherein the PMA structure comprises iron-palladium (FePd) alloy.

Clause 25. The method of clause 24, wherein forming the seed layer comprises sputtering the seed layer on the surface of the silicon wafer substrate.

Clause 26. The method of clause 25, wherein sputtering the seed layer comprises at least one of direct-current magnetron sputtering or RF sputtering.

Clause 27. The method of any of clauses 24-26, wherein forming the PMA structure comprises epitaxially growing the PMA structure formed on the seed layer.

Clause 28. The method of any of clauses 24-27, wherein the silicon wafer comprises both elemental silicon (Si) and silicon dioxide (SiO₂).

Clause 29. The method of any of clauses 24-28, wherein the surface of the silicon wafer substrate silicon wafer is an amorphous SiO₂ surface.

Clause 30. The method of any of clauses 24-29, wherein the seed layer comprises magnesium oxide (MgO) or strontium titanate (SrTiO₃) having an (001) texture.

Clause 31. The method of any of clauses 24-30, wherein the seed layer is polycrystalline.

Clause 32. The method of any of clauses 24-31, wherein the seed layer is a thin film having a thickness measured normal to the surface of the silicon wafer substrate of from about 0.5 nanometers to about 20 nanometers, or from about 1 nanometer to about 8 nanometers, or from about 2 nanometers to about 7 nanometers.

Clause 33. The method of any clauses 24-32, wherein the seed layer is exposed to thermal processing in an N₂ environment for a duration from about 1 minute to 60 minutes, or from about 10 minutes to 50 minutes, or from about 20 minutes to 40 minutes at a fixed temperature from about 100 degrees C. to 800 degrees C., or from about 300 degrees C. to 700 degrees C., or from about 400 degrees C. to 600 degrees C.

Clause 34. The method of clauses 24-33, wherein the seed layer is exposed to thermal processing in an O₂ environment for a duration from about 1 minute to 60 minutes, or from about 10 minutes to 50 minutes, or from about 20 minutes to 40 minutes at a fixed temperature from about 100 degrees C. to 800 degrees C., or from about 300 degrees C. to 700 degrees C., or from about 400 degrees C. to 600 degrees C.

Clause 35. The method of any of clauses 24-34, wherein the FePd alloy defines an L1₀-phase structure.

Clause 36. The method of any of clauses 24-35, further comprising forming at least one bridge layer between the seed layer and the PMA structure.

Clause 37. The method of clause 36, wherein forming the at least one bridge layer comprises forming two bridge layers including a first bridge layer and a second bridge layer.

Clause 38. The method of clause 36, wherein forming at least one bridge layer includes forming a first bridge layer, wherein forming the first bridge layer includes a thermal processing step in a vacuum environment for a duration from about 1 minute to 30 minutes, or from about 2 minutes to 20 minutes, or from about 5 minutes to 15 minutes at a fixed temperature from about 100 degrees C. to 800 degrees C., or from about 300 degrees C. to 700 degrees C., or from about 400 degrees C. to 600 degrees C.

Clause 39. The method of clause 37, further comprising forming a second bridge layer subsequent to forming the first bridge layer, wherein forming the second bridge layer includes a thermal processing step in a vacuum environment for a duration from about 1 minute to 30 minutes, or from about 2 minutes to 20 minutes, or from about 5 minutes to 15 minutes at a fixed temperature from about 100 degrees C. to 800 degrees C., or from about 300 degrees C. to 700 degrees C., or from about 400 degrees C. to 600 degrees C.

Clause 40. The method of clause 37, wherein the first bridge layer comprises chromium and the second bridge layer comprises platinum.

Clause 41. The method of clause 40, wherein the first bridge layer and the second bridge layer each define a respective thickness measured normal to the surface of the silicon wafer substrate, wherein the thickness of the first bridge layer is from about 8 nanometers to about 30 nanometers, and wherein the thickness of the second bridge layer is from about 1 nanometer to about 10 nanometers.

Clause 42. The method of any of clauses 24-41, wherein the PMA structure defines a thickness measured normal to the surface of the silicon wafer substrate, wherein the thickness is from about 2 nanometers to about 15 nanometers.

Clause 43. The method of any of clauses 24-42, wherein forming the PMA structure comprises forming a plurality of sub-layers that form a synthetic antiferromagnetic (SAF) structure.

Clause 44. The method of clause 43, wherein the PMA structure defines three layers including a first sub-layer, a second sub-layer, and a third sub-layer, wherein two of the three sub-layers comprise FePd.

Clause 45. The method of any of clauses 24-44, wherein forming the PMA structure includes a thermal processing step in a vacuum environment for a duration from about 1 minute to 30 minutes, or from about 2 minutes to 20 minutes, or from about 5 minutes to 15 minutes at a fixed temperature from about 100 degrees C. to 800 degrees C., or from about 300 degrees C. to 700 degrees C., or from about 400 degrees C. to 600 degrees C.

Clause 46. The method of any of clauses 24-45, further comprising forming a capping layer on the PMA structure.

Clause 47. The method of any of clauses 24-46, further comprising forming a magnetic tunnel junction bridge layer on the PMA structure.

Clause 48. The method of clause 36, wherein the at least one bridge layer comprises at least one of cobalt manganese silicide (Co₂MnSi), cobalt iron silicide (Co₂FeSi), cobalt manganese aluminide (Co₂MnAl), cobalt iron aluminide (Co₂FeAl), alloys of cobalt iron boride (Co—Fe—B), molybdenum (Mo), ruthenium (Ru), tantalum (Ta), magnesium oxide (MgO) or magnesium aluminum oxide (MgAl₂O₄).

Clause 49. A spin-orbit torque (SOT) MRAM device or a logic device comprising: a silicon wafer substrate; a seed layer formed on a surface of the silicon wafer substrate; a perpendicular magnetic anisotropy (PMA) structure exhibiting crystalline PMA formed on the seed layer, wherein the PMA structure comprises at least one of iron-palladium alloy (FePd), iron-platinum alloy (FePt), or iron-platinum-palladium alloy (Fe(PtₓPd₍₁₋ₓ₎); a magnetic tunnel junction bridge layer including a MgO tunnel barrier; a hard perpendicular magnetic anisotropy (PMA) structure exhibiting PMA formed on the MgO tunnel barrier with a pinned magnetization orientation; and a conducting layer formed on the hard PMA structure, wherein a current delivered through the conducting layer, hard PMA structure, and the PMA structure sets a magnetization state of the PMA structure.

Clause 50. The device of clause 49, wherein the magnetization state of the PMA structure sets a magnetoresistance of the MRAM or logic device.

Clause 51. The device of clauses 49 or 50, wherein the current is used to set the magnetization state of the PMA structure to indicate a logic value.

Clause 52. A device, comprising: a silicon wafer substrate with pre-patterned transistors structures and metal layers including a top metal layer; a seed layer formed on a surface of the top metal layer; and a perpendicular magnetic anisotropy (PMA) structure exhibiting crystalline PMA formed on the seed layer, wherein the PMA structure comprises at least one of iron-palladium (FePd) alloy, iron-platinum alloy (FePt), or iron-platinum-palladium alloy (Fe(PtₓPd₍₁₋ₓ₎).

Clause 53. The device of clause 52, wherein the device comprises at least a portion of a memory device or a logic device.

Clause 54. The device of any of clause 52 or clause 53, wherein the device comprises a magnetic tunnel junction (MTJ), and wherein the PMA structure is a free layer.

Clause 55. The device of any of clauses 1, 49, or 52, wherein the PMA structure is doped with a dopant, and wherein the dopant comprises from about 0.05 atomic percent to about 30% of the PMA structure.

Clause 56. The device of clause 55, wherein the dopant comprises one or more of cobalt (Co), nickel (Ni), copper (Cu), manganese (Mn), vanadium (V), chromium (Cr), or combinations thereof.

1. A device, comprising:
a silicon wafer substrate;
a seed layer formed on a surface of the silicon wafer substrate; and
a perpendicular magnetic anisotropy (PMA) structure exhibiting crystalline PMA formed on the seed layer, wherein the PMA structure comprises at least one of iron-palladium (FePd) alloy, iron-platinum alloy (FePt), or iron-platinum-palladium alloy (Fe(PtₓPd₍₁₋ₓ₎).

2. The device of claim 1, wherein the device comprises at least a portion of a memory device or a logic device.

3. The device of claim 1, wherein the device comprises a magnetic tunnel junction (MTJ), and wherein the PMA structure is a free layer.

4. The device of claim 1, wherein the silicon wafer comprises both elemental silicon (Si) and silicon dioxide (SiO₂).

5. The device of claim 1, wherein the surface of the silicon wafer substrate silicon wafer is an amorphous SiO₂ surface.

6. The device of claim 5, wherein the surface of the silicon wafer substrate defines one or more metallized contacts, and the one or more metallized contacts comprise copper, aluminum, tungsten, or other metals.

7. The device of claim 1, wherein the seed layer comprises at least one of magnesium oxide (MgO) or strontium titanate (SrTiO₃) having an (001) texture.

8. The device of claim 1, wherein the seed layer is polycrystalline.

9. The device of claim 1, wherein the seed layer is a thin film having a thickness measured normal to the surface of the silicon wafer substrate of from about 0.5 nanometers to about 20 nanometers.

10. The device of claim 1, wherein the PMA structure defines an L1₀-phase structure.

11. The device of claim 1, further comprising at least one bridge layer between the seed layer and the PMA structure.

12. The device of claim 11, wherein the at least one bridge layer comprises two bridge layers including a first bridge layer and a second bridge layer.

13. The device of claim 12, wherein the first bridge layer comprises chromium and the second bridge layer comprises platinum.

14. The device of claim 13, wherein the first bridge layer and the second bridge layer each define a respective thickness measured normal to the surface of the silicon wafer substrate,
wherein the thickness of the first bridge layer is from about 8 nanometers to about 30 nanometers, and
wherein the thickness of the second bridge layer is from about 1 nanometer to about 10 nanometers.

15. The device of claim 1, wherein the PMA structure defines a thickness measured normal to the surface of the silicon wafer substrate, wherein the thickness is from about 2 nanometers to about 15 nanometers.

16. The device of claim 1, wherein the PMA structure is formed with a plurality of sub-layers that form a synthetic antiferromagnetic (SAF) structure.

17. The device of claim 16, wherein the sub-layers include three sub-layers, wherein two of the three sub-layers comprise FePd.

18. The device of claim 17, wherein one of the three sub-layers comprises one or more of iridium (Ir), ruthenium (Ru), rhodium (Rh), chromium (Cr), rhenium (Re), osmium (Os), molybdenum (Mo), or combinations thereof.

19. A spin-orbit torque (SOT) MRAM device or a logic device comprising:
a silicon wafer substrate;
a seed layer formed on a surface of the silicon wafer substrate;
a perpendicular magnetic anisotropy (PMA) structure exhibiting crystalline PMA formed on the seed layer, wherein the PMA structure comprises at least one of iron-palladium alloy (FePd), iron-platinum alloy (FePt), or iron-platinum-palladium alloy (Fe(PtₓPd₍₁₋ₓ₎);
a magnetic tunnel junction bridge layer including a MgO tunnel barrier;
a hard perpendicular magnetic anisotropy (PMA) structure exhibiting PMA formed on the MgO tunnel barrier with a pinned magnetization orientation; and
a conducting layer formed on the hard PMA structure, wherein a current delivered through the conducting layer, hard PMA structure, and the PMA structure sets a magnetization state of the PMA structure.

20. A device, comprising:
a silicon wafer substrate with pre-patterned transistors structures and metal layers including a top metal layer;
a seed layer formed on a surface of the top metal layer; and
a perpendicular magnetic anisotropy (PMA) structure exhibiting crystalline PMA formed on the seed layer, wherein the PMA structure comprises at least one of iron-palladium (FePd) alloy, iron-platinum alloy (FePt), or iron-platinum-palladium alloy (Fe(PtₓPd₍₁₋ₓ₎).

21. A method, comprising:
forming a seed layer on a surface of a silicon wafer substrate; and
forming a perpendicular magnetic anisotropy (PMA) structure exhibiting crystalline PMA on the seed layer, wherein the PMA structure comprises at least one of iron-palladium (FePd) alloy, iron-platinum alloy (FePt), or iron-platinum-palladium alloy (Fe(PtₓPd₍₁₋ₓ₎).
